(19) United States
(12) Patent Application Publication
(10) Pub. No.: US 2025/0194080 A1
(43) Pub. Date: Jun. 12, 2025

(54) SEMICONDUCTOR STRUCTURE AND METHOD OF FORMING THE SAME

(71) Applicant: NANYA TECHNOLOGY CORPORATION, New Taipei city (TW)

(72) Inventor: Ying-Cheng CHUANG, Taoyuan City (TW)

(21) Appl. No.: 18/535,053

(22) Filed: Dec. 11, 2023

(51) Int. Cl. H10B 12/00

(52) U.S. Cl. CPC H10B 12/34; H10B 12/053

(57) ABSTRACT

The present disclosure provides a semiconductor structure including a plurality of word line structures in a substrate, in which each one of the word line structures includes a first work function layer, a second work function layer, and a metal layer. The second work function layer is on the first work function layer. The metal layer is in direct contact with the first work function layer and includes a first portion surrounded by the second work function layer.

### BACKGROUND

### Field of Invention

The present disclosure relates to a semiconductor structure and a method of forming the same.

### Description of Related Art

Word lines used in memory devices, such as dynamic random-access memory (DRAM), are connected to the gates to control the switch of the gates in the transistors. As the dimension of the word lines becomes smaller, avoiding gate-induced drain leakage (GIDL) while remaining low enough electrical resistance becomes challenging. Therefore, it is necessary to develop a semiconductor structure and a method of forming the same to satisfy every aspect.

### SUMMARY

The present disclosure provides a semiconductor structure including a plurality of word line structures in a substrate, in which each one of the word line structures includes a first work function layer, a second work function layer, and a metal layer. The second work function layer is on the first work function layer. The metal layer is in direct contact with the first work function layer and includes a first portion surrounded by the second work function layer.

In some embodiments, a work function of the first work function layer is larger than a work function of the second work function layer.

In some embodiments, the second work function layer and the metal layer jointly have a T-shaped cross-section.

In some embodiments, a bottom surface of the metal layer is lower than a top surface of the first work function layer.

In some embodiments, a second portion of the metal layer is surrounded by the first work function layer.

In some embodiments, each one of the word line structures further includes an oxide layer between the first work function layer and the second work function layer.

In some embodiments, a thickness of the second work function layer surrounding the metal layer is from 1.5 nm to 10 nm.

In some embodiments, each one of the word line structures further includes an oxide layer on the second work function layer and the metal layer.

In some embodiments, the semiconductor structure further includes a patterned hard mask layer on a portion of the substrate that is between the word line structures, in which a top surface of the patterned hard mask layer is curved.

The present disclosure also provides a method of forming a semiconductor structure. The method includes the following operations. A plurality of trenches is formed in a substrate. A plurality of first work function layers is formed in the trenches. A plurality of second work function layers is formed on the first work function layers and on sidewalls of the trenches. Portions of the second work function layers and portions of the first work function layers are etched to form a plurality of openings in remaining portions of the second work function layers and remaining portions of the first work function layers. A plurality of metal layers is filled in the openings and the trenches.

In some embodiments, each one of the remaining portions of the second work function layers and a corresponding one of the metal layers jointly have a T-shaped cross-section.

In some embodiments, the method further includes forming an insulating layer on the sidewalls of the trenches before forming the first work function layers.

In some embodiments, the method further includes forming an oxide layer on the first work function layers before forming the second work function layers.

In some embodiments, the method further includes forming an oxide layer on the second work function layers and the metal layers after filling the metal layers.

In some embodiments, the method further includes forming a patterned hard mask layer on the substrate before forming the trenches, and etching a top surface of the patterned hard mask layer to become a curved top surface after filling the metal layers.

In some embodiments, the method further includes filling a nitride layer in the trenches after filling the metal layers.

### BRIEF DESCRIPTION OF THE DRAWINGS

The present disclosure can be more fully understood by reading the following detailed description of the embodiments, with reference made to the accompanying drawings.

FIG. 1 is a cross-section diagram of the semiconductor structure of the present disclosure according to some embodiments.

FIG. 2 is a flow chart of the method of forming the semiconductor structure of the present disclosure according to some embodiments.

FIGS. 3 to 12 are cross-section diagrams in the processes of forming the semiconductor structure according to some embodiments of the method of the present disclosure.

### DETAILED DESCRIPTION

To make the description of the present disclosure more detailed and complete, the following provides an illustrative description of the aspects of the implementation and the specific embodiments of the present disclosure. The disclosure is not to limit the implementation to only one form. The embodiments of the present disclosure may be combined or substituted with each other for a beneficial circumstance, and other embodiments may be appended without further explanation.

Spatially relative terms, such as above and below, etc., may be used in the present disclosure to describe the relation of one element or feature to another element or feature in the figures. The spatially relative terms are intended to encompass different orientations of the device in use or operation in addition to the orientation depicted in the figures. For example, the device may be oriented otherwise, e.g., 90 degrees or other orientations. Therefore, the spatially relative terms in the present disclosure can be interpreted correspondingly. In addition, in the present disclosure, unless otherwise stated, the same or similar reference numbers in different figures refer to the same or similar elements formed from the same or similar materials by the same or similar methods.

The terms “about”, “around”, “approximately”, “basically”, “substantially”, and so on used in the present disclosure include the stated values, characteristics, and the range of deviations from that values and characteristics that can be understood by one skilled in the art. For example, taking into account the errors of values and characteristics, the foregoing terms may include the values within one or more standard deviations (e.g., +5%, +10%, +15%, +20%, or +30%) of the stated value, or include the deviations from the practical operations of the stated characteristics (e.g., the “substantially parallel” may be close to parallel in practice rather than an ideally perfect parallel). In addition, the acceptable range of deviations may be selected according to the measurements or other properties, and not only one kind of deviation may be applicable to all values and characteristics.

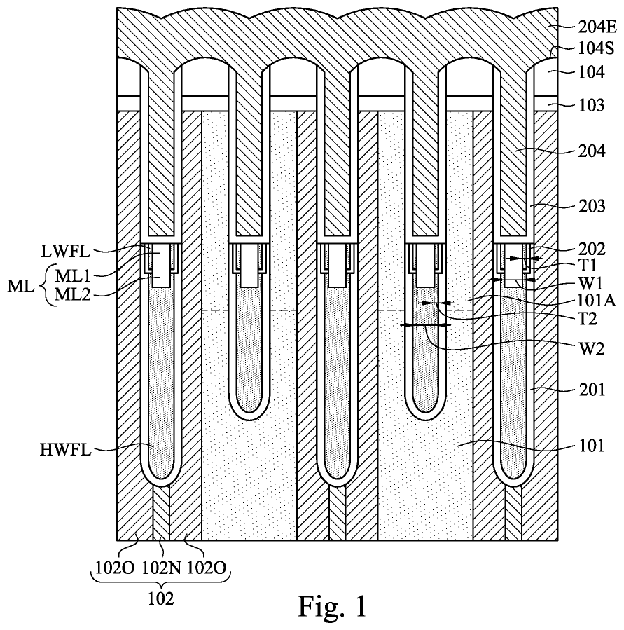

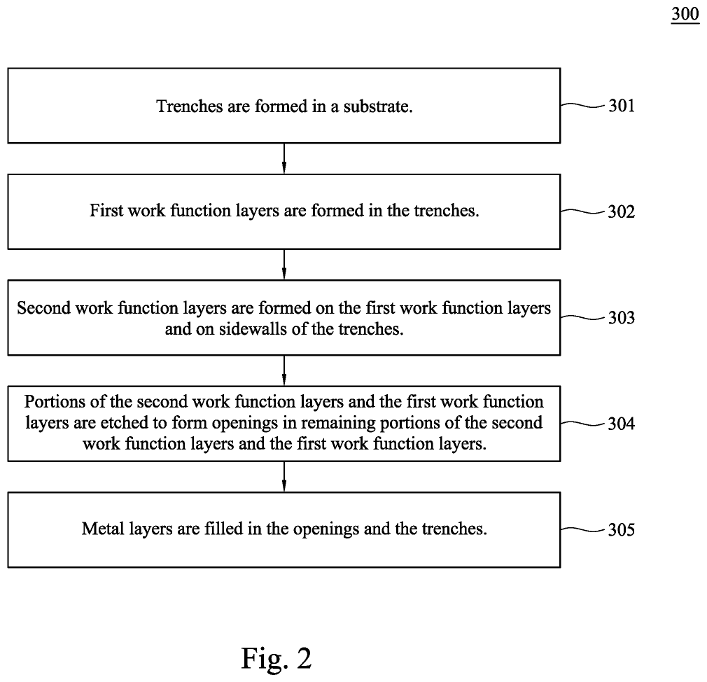

The present disclosure provides a semiconductor structure, as described in FIG. 1. The semiconductor structure includes a plurality of word line structures in a substrate 101. In some embodiments, the word line structures are buried in the substrate 101 to increase the integration density of the semiconductor structure. The number of the word line structures is not limited to the number drawn in the figures and may include any suitable number, such that the word line structures may be repeatedly arranged in the substrate 101, as shown in FIG. 1. Each one of the word line structures includes a first work function layer HWFL, a second work function layer LWFL, and a metal layer ML to reduce the gate-induced drain leakage (GIDL) and the electrical resistance. The second work function layer LWFL is disposed on the first work function layer HWFL. The metal layer ML is in direct contact with the first work function layer HWFL and includes a first portion ML1 surrounded by the second work function layer LWFL. The detailed embodiments of the present disclosure are described below.

The substrate 101 may be a semiconductor substrate and may include elemental semiconductor materials (e.g., carbon, monocrystalline silicon, polycrystalline silicon, amorphous silicon, germanium, tin, sulfur, selenium, tellurium, or the like), compound semiconductor materials (e.g., silicon carbide, boron nitride, aluminum nitride, gallium nitride, gallium phosphide, gallium arsenide, indium phosphide, indium arsenide, indium antimonide, zinc oxide, or the like), alloy semiconductor materials (e.g., SiGe, AlGaAs, InGaAs, InGaP, AlInAs, GaAsP, AlGaN, InGaN, AlGaInP, or the like), or combinations thereof.

The substrate 101 may include active regions 101A separated from each other by an isolation structure 102. The active regions 101A may be doping regions of the substrate 101 and be the source/drain regions of the transistors. In some embodiments, the active regions 101A are the regions of the substrate 101 (e.g., a silicon substrate) doped with an N-type dopant (e.g., phosphorus, antimony, arsenic, or the like) or a P-type dopant (e.g., boron, indium, or the like). The isolation structure 102 surrounds each one of the active regions 101A to provide electrical isolation between the active regions 101A. In some embodiments, the isolation structure 102 may be a shallow trench isolation (STI) structure in the substrate 101. In some embodiments, the preferable isolation structure 102 includes a layered structure, for example, including an oxide layer 102O and a nitride layer 102N. In some embodiments, the oxide layer 102O surrounds the nitride layer 102N and is an outer layer of the isolation structure 102, which is in direct contact with the active regions 101A. The nitride layer 102N is in the center of the isolation structure 102 and sandwiched by the oxide layer 102O. In some embodiments, the oxide layer 102O includes any suitable dielectric oxide material, for example, silicon dioxide, or the like. In some embodiments, the nitride layer 102N includes any suitable dielectric nitride material, for example, silicon nitride, or the like.

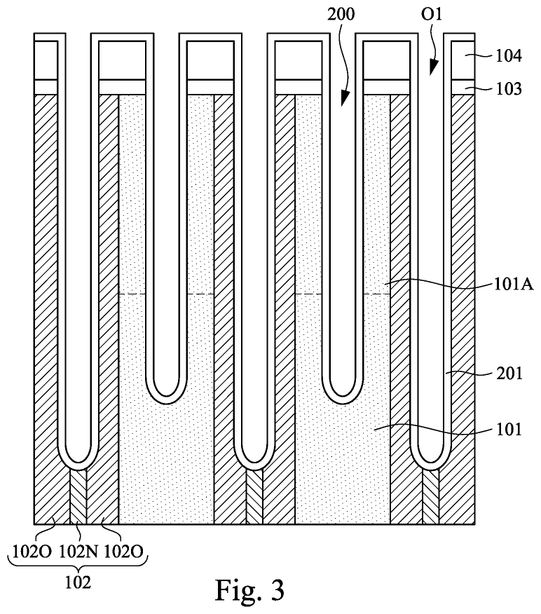

A patterned hard mask layer 104 may be disposed on the substrate 101. The patterned hard mask layer 104 provides a mask to pattern the substrate 101 to form the word line structures in the substrate 101, which the method will be discussed in detail in the following. In some embodiments, the top surface 104S of the patterned hard mask layer 104 is curved to make the nitride layer 204, discussed later, fill in the trenches 200 more easily, where the word line structures are formed in the trenches 200 (see FIGS. 3 to 12). With the help of the curved top surface 104S, the nitride layer 204 may successfully fill in the trenches 200 with smaller widths and thus form the word line structures with smaller dimensions. In some embodiments, the top surface of the patterned hard mask layer 104 may be in direct contact with the nitride layer 204. In some embodiments, the patterned hard mask layer 104 includes silicon nitride, or the like.

A pad oxide layer 103 may be disposed between the substrate 101 and the patterned hard mask layer 104 to relieve the stress between the substrate 101 and the patterned hard mask layer 104. Therefore, a dislocation of the substrate 101 and the patterned hard mask layer 104 induced by the stress difference may be reduced. In some embodiments, the pad oxide layer 103 includes silicon dioxide, or the like.

Each one of the word line structures is disposed in the corresponding one of the trenches 200 in the substrate 101. The first work function layer HWFL, the second work function layer LWFL, and the metal layer ML may be referred to as a part of a gate structure and are surrounded by an insulating layer 201 that may be referred to as a gate oxide, in which the insulating layer 201 of the word line structures is disposed on the sidewalls of the trenches 200. In some embodiments, the thickness of the insulating layer 201 surrounding the second work function layer LWFL and the metal layer ML is smaller than the thickness of the insulating layer 201 surrounding the first work function layer HWFL. In some embodiments, the insulating layer 201 includes silicon dioxide, or the like.

Continue with the description of the word line structures. The work function of the first work function layer HWFL is larger than the work function of the second work function layer LWFL to reduce the gate-induced drain leakage (GIDL). In some embodiments, the first work function layer HWFL is a metal-containing conductive layer and includes, for example, titanium nitride, tungsten, or the like. In some embodiments, the second work function layer LWFL is a silicon-containing conductive layer and includes, for example, polysilicon, or the like. The metal layer ML includes a first portion ML1 surrounded by the second work function layer LWFL and a second portion ML2 surrounded by a portion of the first work function layer HWFL. The second portion ML2 is indirect contact with the first work function layer HWFL to reduce the electrical resistance of the word line structures, and the first portion ML1 is wrapped by the second work function layer LWFL to reduce the gate-induced drain leakage (GIDL). In some embodiments, the metal layer ML is a continuous block to perform the present disclosure more easily. In some embodiments, the preferable metal layer ML includes titanium nitride, tungsten, or a combination thereof. In some embodiments, the metal layer ML and the second work function layer LWFL jointly have a T-shaped cross-section, as shown in FIG. 1, in which the top surface of the metal layer ML is aligned with the top surface of the second work function layer LWFL, and the bottom surface of the metal layer ML is lower than the bottom surface of the second work function layer LWFL. In some embodiments, a thickness T1 of the second work function layer LWFL surrounding the first portion ML1 of the metal layer ML is preferably from 1.5 nm to 10 nm, for example, 1.5 nm, 3.2 nm, 4.9 nm, 5.6 nm, 7.3 nm, or 10 nm, and a width W1 of the first portion ML1 of the metal layer ML that is surrounded by the second work function layer LWFL is preferably from 2 times to 4 times of the thickness T1 of the second work function layer LWFL (i.e., the width W1 of the first portion ML1 of the metal layer ML is preferably from 3 nm to 40 nm, for example, 3 nm, 6 nm, 10 nm, 15 nm, 20 nm, 25 nm, 30 nm, or 40 nm). When the thickness T1 of the second work function layer LWFL is larger than the foregoing range or the width W1 of the metal layer ML is smaller than the foregoing range, the electrical resistance of the word line structures may significantly increase to an unsatisfying level. When the thickness T1 of the second work function layer LWFL is smaller than the foregoing range or the width W1 of the metal layer ML is larger than the foregoing range, the gate-induced drain leakage (GIDL) may not be significantly reduced.

For more detail of the first work function layer HWFL, the second work function layer LWFL, and the metal layer ML, in some embodiments, the bottom surface of the metal layer ML is lower than the top surface of the first work function layer HWFL. In some embodiments, the side surface of the second work function layer LWFL is substantially aligned with the side surface of the first work function layer HWFL. In some embodiments, a thickness T2 of the portion of the first work function layer HWFL that surrounds the second portion ML2 of the metal layer ML is substantially the same as the thickness T1 of the second work function layer LWFL that surrounds the first portion ML1 of the metal layer ML. In some embodiments, a width W2 of the second portion ML2 of the metal layer ML is substantially the same as the width W1 of the first portion ML1 of the metal layer ML.

Continue with the description of the word line structures. In some embodiments, a first oxide layer 202 of each one of the word line structures is disposed between the first work function layer HWFL and the second work function layer LWFL to provide adhesion to the second work function layer LWFL. In some embodiments, in addition to covering the bottom surface of the second work function layer LWFL, the first oxide layer 202 extends continuously to cover the side surface of the second work function layer LWFL. In some embodiments, the portion of the first oxide layer 202 covering the side surface of the second work function layer LWFL is disposed between the second work function layer LWFL and the insulating layer 201. In some embodiments, the first oxide layer 202 includes silicon dioxide, or the like. In some embodiments, a second oxide layer 203 of each one of the word line structures is disposed on the second work function layer LWFL and the metal layer ML to provide adhesion to the second work function layer LWFL. In some embodiments, in addition to covering the top surfaces of the second work function layer LWFL and the metal layer ML, the second oxide layer 203 extends continuously to cover the side surface of the corresponding one of the trenches 200. In some embodiments, the second oxide layer 203 includes silicon dioxide, or the like. In the embodiments including the first oxide layer 202 and/or the second oxide layer 203, the second work function layer LWFL (and the metal layer ML) may stay much fixedly in the trenches 200 and may not easily fall off from the semiconductor structure.

Continue with the description of the word line structures. A nitride layer 204 is disposed on the second work function layer LWFL and the metal layer ML (and on the second oxide layer 203 in some embodiments) in the trenches 200. The nitride layer 204 disposed in the trenches 200 may be part of the word line structures to provide electrical insulation for the word line structures. In some embodiments, the nitride layer 204 may include an extending portion 204E covering the top surface of the substrate 101, as shown in FIG. 1, or may exclude the extending portion 204E that covers the top surface of the substrate 101 (not shown in the figures). In some embodiments, the nitride layer 204 includes dielectric material, for example, silicon nitride, or the like.

In some embodiments, a first barrier layer (not shown in the figures) of each one of the word line structures may be disposed between the first work function layer HWFL and the insulating layer 201 to inhibit the spread of the impurity between the first work function layer HWFL and the substrate 101. In some embodiments, the first barrier layer includes any suitable material, for example, titanium nitride, tungsten nitride, tantalum nitride, or the like. In some embodiments, a second barrier layer (not shown in the figures) of each one of the word line structures may be disposed between the first work function layer HWFL and the first oxide layer 202 to inhibit the spread of the impurity between the first work function layer HWFL and the second work function layer LWFL. In some embodiments, the second barrier layer includes any suitable material, for example, titanium nitride, tungsten nitride, tantalum nitride, or the like.

The present disclosure also provides a method 300 of forming the semiconductor structure described above. The method 300 includes an operation 301 to an operation 305. The operation 301 includes forming a plurality of trenches 200 in the substrate 101. The operation 302 includes forming a plurality of first work function layers HWFL in the trenches 200. The operation 303 includes forming a plurality of second work function layers LWFL on the first work function layers HWFL and on sidewalls of the trenches 200. The operation 304 includes etching portions of the second work function layers LWFL and portions of the first work function layers HWFL to form a plurality of openings O2 in remaining portions of the second work function layers LWFL and remaining portions of the first work function layers HWFL. The operation 305 includes filling a plurality of metal layers ML in the openings O2 and the trenches 200. The detailed embodiments of the present disclosure are described below.

Before the operation 301, as shown in FIG. 3, portions of the substrate 101 may be doped with an N-type dopant or a P-type dopant by any suitable method, for example, an ion implantation process, to form the active regions 101A. The isolation structure 102 may be formed by etching a portion of the substrate 101 to form a trench that may be filled with the material of the isolation structure 102. The pad oxide layer 103 may be deposited on the substrate 101 by any suitable method, for example, chemical vapor deposition or physical vapor deposition. The material of the patterned hard mask layer 104 may be deposited on the substrate 101 by any suitable method, for example, chemical vapor deposition or physical vapor deposition.

In the operation 301, as shown in FIG. 3, the trenches 200 are formed. In some embodiments, the trenches 200 are formed by etching the material under the openings O1 of the patterned hard mask layer 104. The position of the openings O1 of the patterned hard mask layer 104 defines the position of the trenches 200. The openings O1 of the patterned hard mask layer 104 may be formed by deposing a patterned photoresist layer (not shown in the figures) on the material of the patterned hard mask layer 104 and then transferring the patterns of the patterned photoresist layer to the material of the patterned hard mask layer 104 to form the patterned hard mask layer 104. The patterned photoresist layer may be formed by any suitable photolithography method. Since the material of the isolation structure 102 may be different than the material of the rest of the substrate 101, the formed trenches 200 may have different etch depths, as shown in FIG. 3, owing to different etch rates. After the operation 301, the material of the insulating layer 201 may conformally form on the sidewalls of the trenches 200 by, for example, atomic layer deposition (ALD), in-situ steam generation (ISSG), or a combination thereof.

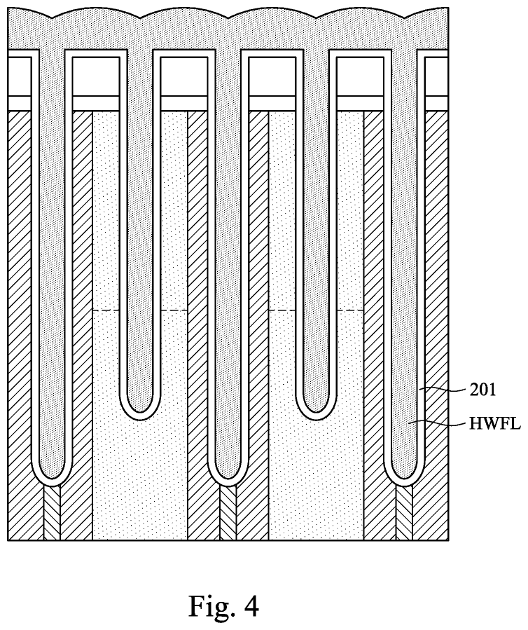

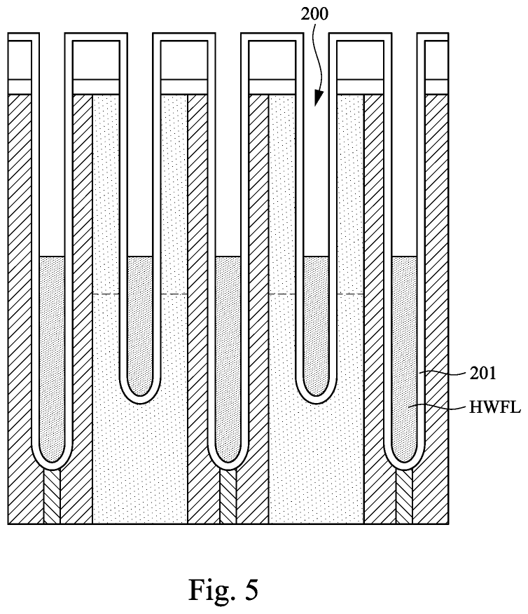

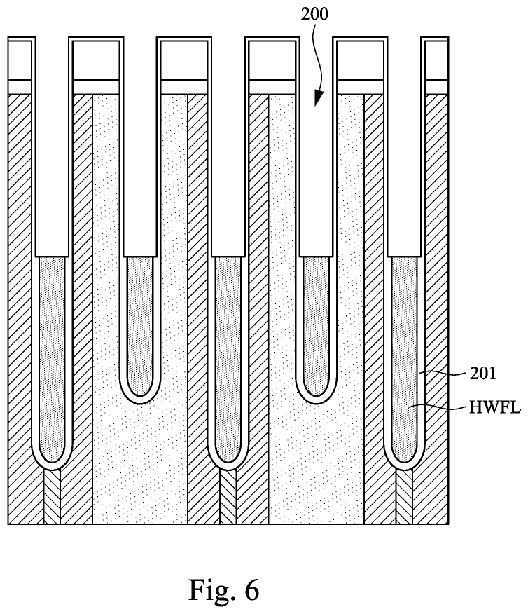

In the operation 302, as shown in FIGS. 4 to 5, the first work function layers HWFL are formed in the trenches 200 by any suitable deposition method and then etched back by any suitable etching method to remain the first work function layers HWFL at the bottom of the trenches 200. After the operation 302, a clean process may be performed to clean the undesired residue of the first work function layers HWFL, so the first oxide layers 202, the second work function layers LWFL, the metal layers ML, the second oxide layers 203, and the nitride layer 204 formed in the subsequent processes may form on the sidewalls of the trenches 200 substantially without the residue of the first work function layers HWFL attached thereon. In some embodiments, the clean process includes a wet etching process. After the clean process, a portion of the material of the insulating layer 201 that is above the first work function layers HWFL may be removed as well, such that the thickness of the portion of the material of the insulating layer 201 that is above the first work function layers HWFL may be smaller than the thickness of the remaining portion of the material of the insulating layer 201 that is below the top surfaces of the first work function layers HWFL, as shown in FIG. 6.

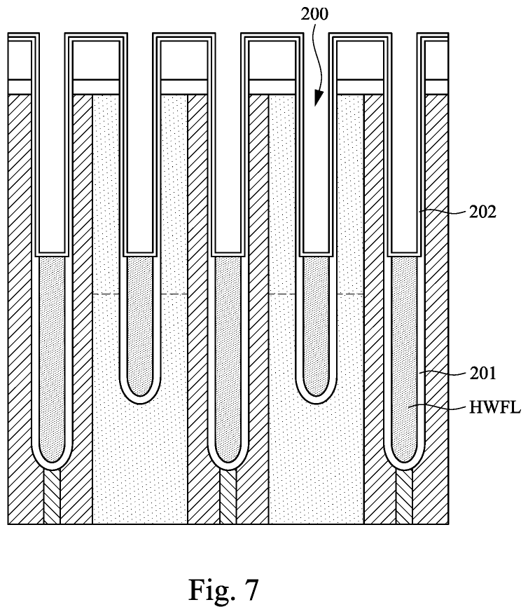

After the operation 302, the material of the first oxide layer 202 may conformally form on the sidewalls of the trenches 200 and on the material of the insulating layer 201 and the first work function layers HWFL, as shown in FIG. 7. In some embodiments, forming the material of the first oxide layer 202 may include any suitable method, for example, atomic layer deposition (ALD).

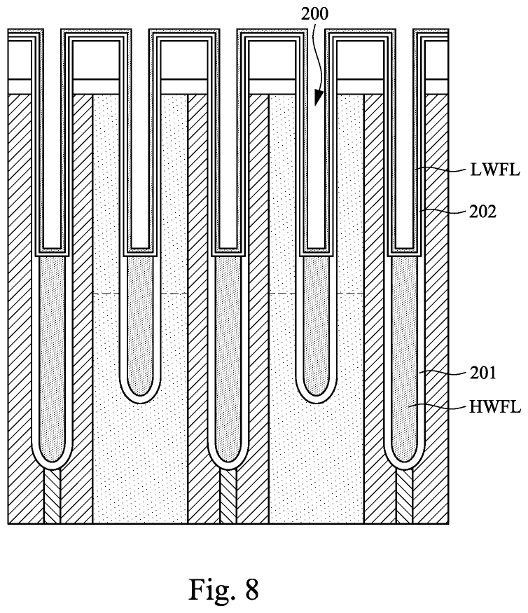

In the operation 303, as shown in FIG. 8, the material of the second work function layer LWFL is formed on the first work function layers HWFL and on the sidewalls of the trenches 200 (and on the material of the first oxide layer 202 in some embodiments). In some embodiments, the material of the second work function layer LWFL is conformally formed on the first work function layers HWFL and on the sidewalls of the trenches 200 by, for example, atomic layer deposition (ALD).

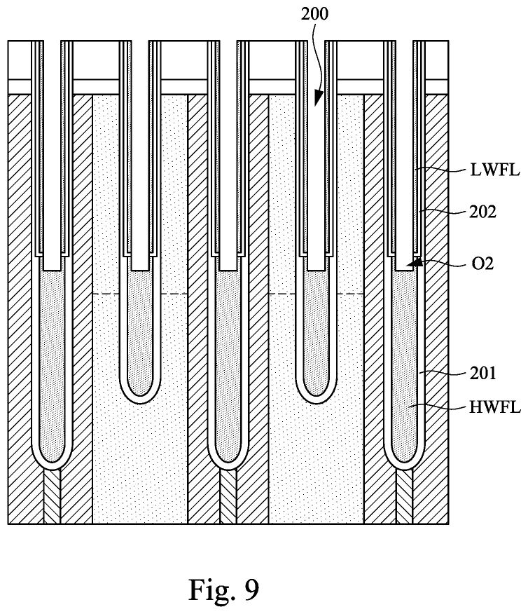

In the operation 304, as shown in FIG. 9, portions of the material of the second work function layer LWFL and the first work function layers HWFL (and the material of the first oxide layer 202 in some embodiments) are etched to form the openings O2 that may be filled with the material of the metal layer ML in the subsequent processes. In some embodiments, the etching method includes a dry etching process.

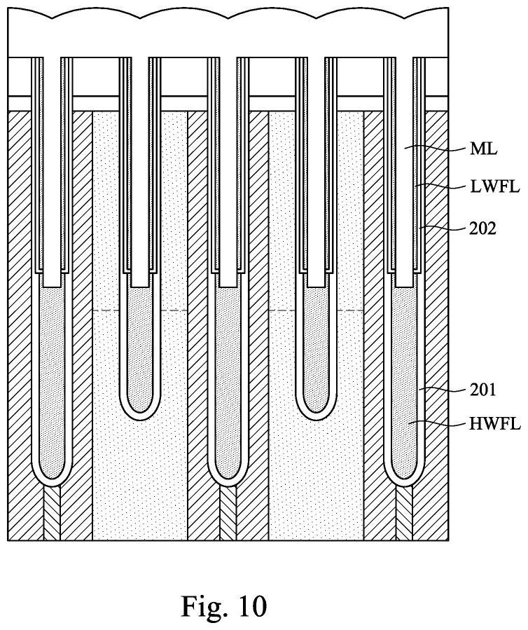

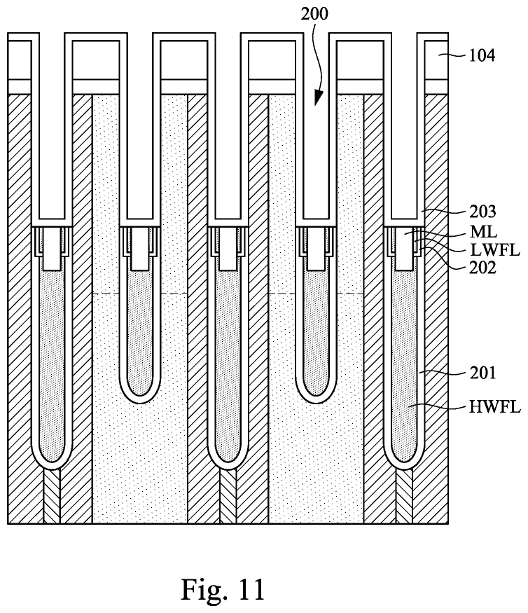

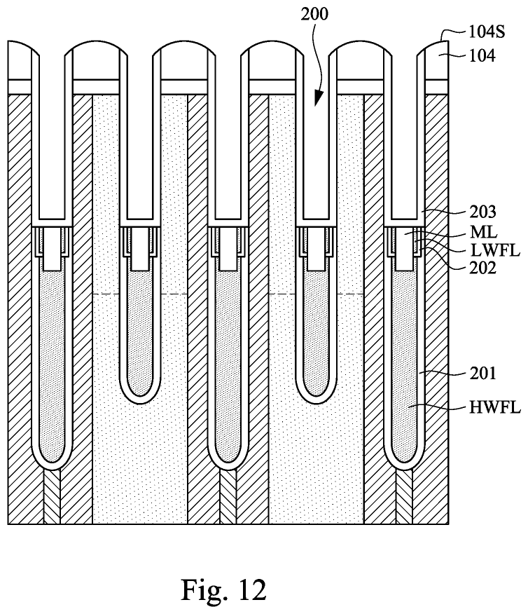

In the operation 305, as shown in FIGS. 10 to 11, the material of the metal layer ML is filled in the openings O2 and the trenches 200 by, for example, chemical vapor deposition or physical vapor deposition. In some embodiments, the filled metal layer ML may be etched back along with portions of the materials of the second work function layer LWFL and the insulating layer 201 (and the first oxide layer 202 in some embodiments) to expose the upper portions of the trenches 200. In some embodiments, the etching method includes a dry etching process. After the operation 305, the material of the second oxide layer 203 may form on the second work function layers LWFL and the metal layers ML and on the sidewalls of the trenches 200. In some embodiments, the material of the second oxide layer 203 is conformally formed by, for example, atomic layer deposition (ALD). After the material of the second oxide layer 203 is formed, an etching process, for example, a dry etching process or a wet etching process, may be performed to etch the patterned hard mask layer 104, such that the top surface 104S of the patterned hard mask layer 104, after etching, is curved. After the formation of the curved top surface 104S of the patterned hard mask layer 104, the patterned hard mask layer 104 is exposed and portions of the material of the second oxide layer 203 may be removed as well, as shown in FIG. 12. After the patterned hard mask layer 104 is etched, the nitride layer 204 may be filled in the trenches 200 by any suitable deposition method, for example, chemical vapor deposition or physical vapor deposition. After the formation of the nitride layer 204, the semiconductor structure, as shown in FIG. 1 may be obtained. In some embodiments, the nitride layer 204 may include the extending portion 104E that is on the substrate 101 and above the word line structures, and the extending portion 104E may be removed by any suitable method, for example, chemical mechanical planarization, or chemical mechanical polishing.

The semiconductor structure of the present disclosure and the semiconductor structure derived from the method of the present disclosure provide the word line structures having reduced gate-induced drain leakage (GIDL) and electrical resistance to significantly improve the performance of the semiconductor structure in the application of, for example, the dynamic random-access memory (DRAM) device having smaller dimension. The method of the present disclosure is easy to implement, thus significantly improving the yield of forming the semiconductor structure.

The present disclosure is described in detail with some embodiments, but other embodiments may be applicable. Therefore, the description of the embodiments in the present disclosure should not be used to limit the scope and spirit of the appended claims.

For one skilled in the art, modifications and changes to the present disclosure may be made without departing from the scope and spirit of the present disclosure. The present disclosure is intended to cover the foregoing modifications and changes as long as such modifications and changes are within the scope and spirit of the appended claims.

What is claimed is:

1. A semiconductor structure, comprising:
a plurality of word line structures in a substrate, wherein each one of the word line structures comprises:
a first work function layer;
a second work function layer on the first work function layer; and
a metal layer in direct contact with the first work function layer and comprising a first portion surrounded by the second work function layer.

2. The semiconductor structure of claim 1, wherein a work function of the first work function layer is larger than a work function of the second work function layer.

3. The semiconductor structure of claim 1, wherein the second work function layer and the metal layer jointly have a T-shaped cross-section.

4. The semiconductor structure of claim 1, wherein a bottom surface of the metal layer is lower than a top surface of the first work function layer.

5. The semiconductor structure of claim 1, wherein a second portion of the metal layer is surrounded by the first work function layer.

6. The semiconductor structure of claim 1, wherein each one of the word line structures further comprises an oxide layer between the first work function layer and the second work function layer.

7. The semiconductor structure of claim 1, wherein a thickness of the second work function layer surrounding the metal layer is from 1.5 nm to 10 nm.

8. The semiconductor structure of claim 1, wherein each one of the word line structures further comprises an oxide layer on the second work function layer and the metal layer.

9. The semiconductor structure of claim 1, further comprising a patterned hard mask layer on a portion of the substrate that is between the word line structures, wherein a top surface of the patterned hard mask layer is curved.

10. A method of forming a semiconductor structure, comprising:
forming a plurality of trenches in a substrate;
forming a plurality of first work function layers in the trenches;
forming a plurality of second work function layers on the first work function layers and on sidewalls of the trenches;
etching portions of the second work function layers and portions of the first work function layers to form a plurality of openings in remaining portions of the second work function layers and remaining portions of the first work function layers; and
filling a plurality of metal layers in the openings and the trenches.

11. The method of claim 10, wherein each one of the remaining portions of the second work function layers and a corresponding one of the metal layers jointly have a T-shaped cross-section.

12. The method of claim 10, further comprising forming an insulating layer on the sidewalls of the trenches before forming the first work function layers.

13. The method of claim 10, further comprising forming an oxide layer on the first work function layers before forming the second work function layers.

14. The method of claim 10, further comprising forming an oxide layer on the second work function layers and the metal layers after filling the metal layers.

15. The method of claim 10, further comprising:
forming a patterned hard mask layer on the substrate before forming the trenches; and
etching a top surface of the patterned hard mask layer to become a curved top surface after filling the metal layers.

16. The method of claim 10, further comprising filling a nitride layer in the trenches after filling the metal layers.
